(19) United States
(12) Patent Application Publication
(10) Pub. No.: US 2018/0130723 A1
(43) Pub. Date: May 10, 2018

(54) LEADFRAME SUBSTRATE WITH ELECTRONIC COMPONENT INCORPORATED THEREIN AND SEMICONDUCTOR ASSEMBLY USING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/863,998

(22) Filed: Jan. 8, 2018

Related U.S. Application Data
(63) Continuation-in-part of application No. 14/621,332, filed on Feb. 12, 2015.
Application No. 14/621,332 is a continuation-in-part of application No. 14/846,987, filed on Sep. 7, 2015.
Application No. 14/846,987 is a continuation-in-part of application No. 15/642,253, filed on Jul. 5, 2017.
Application No. 15/642,253 is a continuation-in-part of application No. 15/642,256, filed on Jul. 5, 2017.
Application No. 14/846,987 is a continuation-in-part of application No. 14/621,332, filed on Feb. 12, 2015.
Application No. 15/642,253 is a continuation-in-part of application No. 14/621,332, filed on Feb. 12, 2015.
Application No. 14/621,332 is a continuation-in-part of application No. 14/846,987, filed on Sep. 7, 2015.
(60) Provisional application No. 61/949,652, filed on Mar. 7, 2014.

(51) Int. Cl. H01L 23/495; H01L 21/48

(52) U.S. Cl. CPC H01L 23/49527; H01L 23/49503; H01L 23/4952; H01L 21/4825; H01L 23/49568; H01L 21/4828; H01L 23/49541

(57) ABSTRACT

The leadframe substrate includes a routing circuitry disposed on a compound layer and electrically connects an electronic component encapsulated in the compound layer to metal leads. The compound layer fills in spaces between the metal leads and provides a dielectric platform for the routing circuitry deposited thereon. The routing circuitry laterally extends on the compound layer and is electrically coupled to the electronic component and the metal leads.

### CROSS REFERENCE TO RELATED APPLICATIONS

This application is a continuation-in-part of U.S. application Ser. No. 14/621,332 filed Feb. 12, 2015, a continuation-in-part of U.S. application Ser. No. 14/846,987 filed Sep. 7, 2015, a continuation-in-part of U.S. application Ser. No. 15/642,253 filed Jul. 5, 2017 and a continuation-in-part of U.S. application Ser. No. 15/642,256 filed Jul. 5, 2017. The U.S. application Ser. No. 14/846,987 is a continuation-in-part of U.S. application Ser. No. 14/621,332 filed Feb. 12, 2015. The U.S. application Ser. No. 15/642,253 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 14/621,332 claims the benefit of filing date of U.S. Provisional Application Ser. No. 61/949,652 filed Mar. 7, 2014. The entirety of each of said applications is incorporated herein by reference.

### FIELD OF THE INVENTION

The present invention relates to a leadframe substrate and, more particularly, to a leadframe substrate having a routing circuitry electrically coupling an electronic component encapsulated in a compound layer to metal leads, and a semiconductor assembly using the same.

### DESCRIPTION OF RELATED ART

A leadframe is a structure that provides electrical interconnections for a semiconductor die mounted on it. That is, a die is attached to a leadframe and then bonding pads of the die are electrically connected to leads of the leadframe, typically by gold or copper wires through a wire bonding process. The die, leadframe and wires are then encapsulated with a plastic mold compound. As disclosed in U.S. Pat. Nos. 6,396,139, 6,696,747, 7,049,684, and 8,354,741, leadframe packages possess many advantages for high-speed circuits including high thermal management capability, low cost and superior electrical performances in high frequency applications. However, because the etching-formed leadframes are coarse in lead width and space, the limited routing capability has resulted in a rapid replacement by the use of laminate substrates for high pin-count devices such as Ball-Grid Array (“BGA”) packages, which are less reliable, poor in heat dissipation and expensive.

It would be advantageous to have a leadframe substrate that can offer high density interconnects and embedded electronic component so as to accommodate high-pin count semiconductor devices with better signal integrity, and also take full advantages of the benefits of metal leads in terms of mechanical reliability and superior electrical performances.

### SUMMARY OF THE INVENTION

The objective of the present invention is to provide a leadframe substrate having a routing circuitry disposed on a compound layer and electrically coupling an electronic component encapsulated in the compound layer to a plurality of metal leads. The compound layer provides a dielectric platform around the electronic component and the metal leads, whereas the routing circuitry disposed on the compound layer provides interconnection between the metal leads and between the metal leads and the electronic component.

In accordance with the foregoing and other objectives, the present invention provides a leadframe substrate with electronic component incorporated therein, comprising: a plurality of metal leads each having an inner end directed toward a predetermined area and an outer end situated farther away from the predetermined area than the inner end; an electronic component that is disposed at the predetermined area and has a top side substantially coplanar with top sides of the metal leads; a compound layer that fills in spaces between the metal leads and laterally extends beyond the inner ends of the metal leads and into the predetermined area and encapsulates the electronic component, wherein the compound layer has a top surface substantially coplanar with the top sides of the metal leads; and a top routing circuitry disposed on the top surface of the compound layer and electrically coupling the electronic component to at least one of the metal leads. Optionally, the leadframe substrate may further comprise a bottom routing circuitry disposed at a bottom surface of the compound layer and electrically connected to the top routing circuitry through the metal leads or metallized through holes in the compound layer. Further, the present invention also provides a semiconductor assembly that includes a semiconductor device electrically coupled to the top routing circuitry or the bottom routing circuitry of the aforementioned leadframe substrate.

The leadframe substrate and the semiconductor assembly using the same according to the present invention have numerous advantages. For instance, providing the metal leads can offer horizontal routing and vertical connecting channels between two opposites side of the leadframe substrate. Binding the compound layer to the leadframe can provide a platform for high resolution circuitries disposed thereon. Depositing the top routing circuitry on the compound layer can enhance routing flexibility of the leadframe substrate and electrically couple the electronic component to the metal leads so as to improve electrical characteristics of the assembly and allow fine pitch assemblies such as flip chip and surface mount component to be assembled thereon and interconnected to the metal leads by the top routing circuitry.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional schematic and bottom perspective views, respectively, of a leadframe in accordance with the first embodiment of the present invention;

FIGS. 3 and 4 are cross-sectional schematic and bottom perspective views, respectively, of the structure of FIGS. 1 and 2 further provided with a carrier film in accordance with the first embodiment of the present invention;

FIGS. 5 and 6 are cross-sectional schematic and bottom perspective views, respectively, of the structure of FIGS. 3 and 4 further provided with electronic components in accordance with the first embodiment of the present invention;

FIGS. 7 and 8 are cross-sectional schematic and bottom perspective views, respectively, of the structure of FIGS. 5 and 6 further provided with a compound layer in accordance with the first embodiment of the present invention;

FIGS. 9 and 10 are cross-sectional schematic and top perspective views, respectively, of the structure after removal of the carrier film from the surface of FIGS. 7 and 8 in accordance with the first embodiment of the present invention;

FIGS. 11 and 12 are cross-sectional schematic and top perspective views, respectively, of the structure of FIGS. 9 and 10 further provided with a top routing circuitry in accordance with the first embodiment of the present invention;

FIGS. 13 and 14 are cross-sectional schematic and top perspective views, respectively, of a leadframe substrate trimmed from the structure of FIGS. 11 and 12 in accordance with the first embodiment of the present invention;

FIGS. 15 and 16 are cross-sectional schematic and top perspective views, respectively, of the structure of FIGS. 13 and 14 further provided with a semiconductor device and a passive component in accordance with the first embodiment of the present invention;

FIGS. 17 and 18 are cross-sectional schematic and bottom perspective views, respectively, of another aspect of the leadframe substrate in accordance with the first embodiment of the present invention;

FIG. 19 is a cross-sectional schematic view of the structure of FIGS. 17 and 18 further provided with a semiconductor device in accordance with the first embodiment of the present invention;

FIG. 20 is a cross-sectional schematic view of yet another aspect of the leadframe substrate in accordance with the first embodiment of the present invention;

FIG. 21 is a cross-sectional schematic view of the structure of FIG. 20 further provided with a semiconductor device in accordance with the first embodiment of the present invention;

FIG. 22 is a cross-sectional schematic view of yet another aspect of the leadframe substrate in accordance with the first embodiment of the present invention;

FIG. 23 is a cross-sectional schematic view of the structure of FIG. 22 further provided with a semiconductor device in accordance with the first embodiment of the present invention;

FIGS. 24 and 25 are cross-sectional schematic and bottom perspective views, respectively, of a leadframe in accordance with the second embodiment of the present invention;

FIGS. 26 and 27 are cross-sectional schematic and bottom perspective views, respectively, of the structure of FIGS. 24 and 25 further provided with a carrier film in accordance with the second embodiment of the present invention;

FIGS. 28 and 29 are cross-sectional schematic and bottom perspective views, respectively, of the structure of FIGS. 26 and 27 further provided with electronic components in accordance with the second embodiment of the present invention;

FIGS. 30 and 31 are cross-sectional schematic and bottom perspective views, respectively, of the structure of FIGS. 28 and 29 further provided with a compound layer in accordance with the second embodiment of the present invention;

FIGS. 32 and 33 are cross-sectional schematic and top perspective views, respectively, of the structure after removal of the carrier film from the surface of FIGS. 30 and 31 in accordance with the second embodiment of the present invention;

FIGS. 34 and 35 are cross-sectional schematic and top perspective views, respectively, of the structure of FIGS. 32 and 33 further provided with a top routing circuitry in accordance with the second embodiment of the present invention;

FIGS. 36 and 37 are cross-sectional schematic and top perspective views, respectively, of a leadframe substrate trimmed from the structure of FIGS. 34 and 35 in accordance with the second embodiment of the present invention;

FIGS. 38 and 39 are cross-sectional schematic and top perspective views, respectively, of the structure of FIGS. 36 and 37 further provided with a semiconductor device in accordance with the second embodiment of the present invention;

FIG. 40 is a cross-sectional schematic view of another aspect of the leadframe substrate in accordance with the second embodiment of the present invention;

FIG. 41 is a cross-sectional schematic view of the structure of FIG. 40 further provided with a semiconductor device in accordance with the second embodiment of the present invention;

FIG. 42 is a cross-sectional schematic view of yet another aspect of the leadframe substrate in accordance with the second embodiment of the present invention;

FIG. 43 is a cross-sectional schematic view of the structure of FIG. 42 further provided with a semiconductor device in accordance with the second embodiment of the present invention;

FIG. 44 is a cross-sectional schematic view of yet another aspect of the leadframe substrate in accordance with the second embodiment of the present invention;

FIG. 45 is a cross-sectional schematic view of the structure of FIG. 44 further provided with a semiconductor device in accordance with the second embodiment of the present invention;

FIGS. 46 and 47 are cross-sectional schematic and top perspective views, respectively, of a leadframe substrate in accordance with the third embodiment of the present invention;

FIGS. 48 and 49 are cross-sectional schematic and top perspective views, respectively, of the structure of FIGS. 46 and 47 further provided with a semiconductor device and a passive component in accordance with the third embodiment of the present invention;

FIG. 50 is a cross-sectional schematic view of another aspect of the leadframe substrate in accordance with the third embodiment of the present invention;

FIG. 51 is a cross-sectional schematic view of the structure of FIG. 50 further provided with a semiconductor device in accordance with the third embodiment of the present invention;

FIG. 52 is a cross-sectional schematic view of yet another aspect of the leadframe substrate in accordance with the third embodiment of the present invention; and

FIG. 53 is a cross-sectional schematic view of the structure of FIG. 52 further provided with a semiconductor device in accordance with the third embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

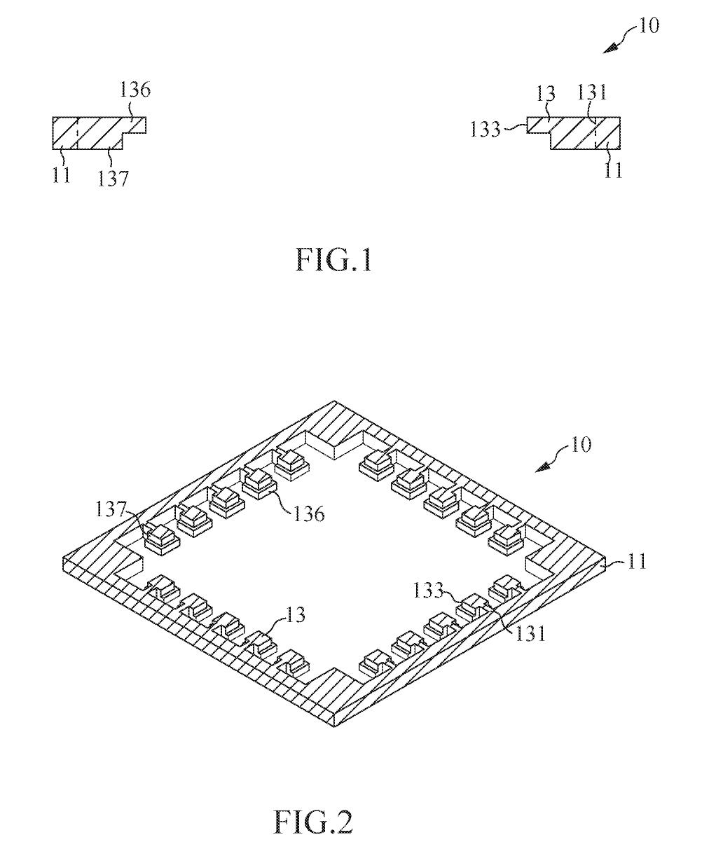

FIGS. 1-14 are schematic views showing a method of making a leadframe substrate that includes a plurality of metal leads, electronic components, a compound layer and a top routing circuitry in accordance with the first embodiment of the present invention.

FIGS. 1 and 2 are cross-sectional schematic and bottom perspective views, respectively, of a leadframe 10. The leadframe 10 typically is made of copper alloys, steel or alloy 42, and can be formed by a wet etching or stamping/punching process from a rolled metal strip having a thickness in a range from about 0.15 mm to about 1.0 mm. The etching process may be a one-sided or two-sided etching to etch through the metal strip and thereby transfer the metal strip into a desired overall pattern of the leadframe 10 that includes a metal frame 11 and a plurality of metal leads 13. The metal leads 13 laterally extend from the metal frame 11 toward the central area within the metal frame 11. As a result, the metal leads 13 each have an outer end 131 integrally connected to interior sidewalls of the metal frame 11 and an inner end 133 directed inwardly away from the metal frame 11. Additionally, in this embodiment, the leadframe 10 is further selectively half-etched from its bottom side. Accordingly, the metal leads 13 have stepped peripheral edges. The metal leads 13 each have a horizontally elongated portion 136 and a vertically projected portion 137. The vertically projected portion 137 protrudes from a lower surface of the horizontally elongated portion 136 in the downward direction.

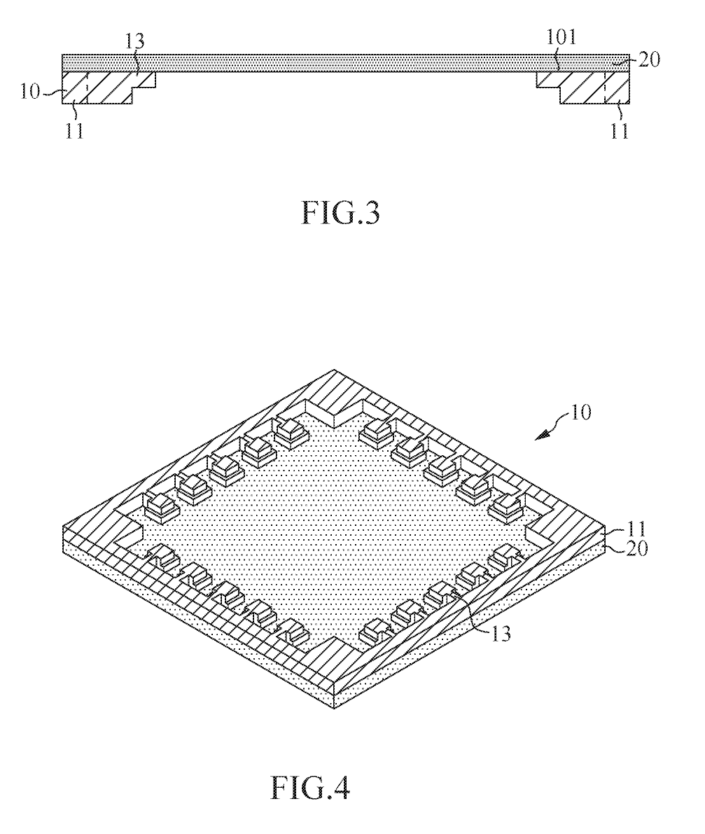

FIGS. 3 and 4 are cross-sectional schematic and bottom perspective views, respectively, of the structure with the leadframe 10 attached to a carrier film 20. The carrier film 20 typically is a tape, and the leadframe 10 is attached to the carrier film 20 with the top side 101 of the leadframe 10 in contact with the carrier film 20.

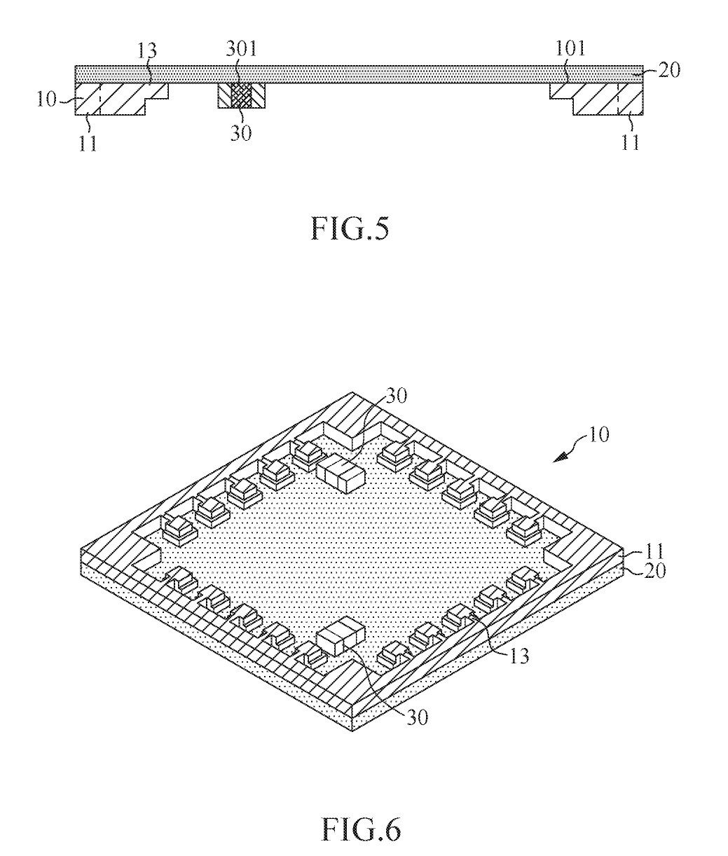

FIGS. 5 and 6 are cross-sectional schematic and bottom perspective views, respectively, of the structure with electronic components 30 attached to the carrier film 20. The electronic components 30 are disposed within the metal frame 11, with the top sides 301 of the electronic components 30 in contact with the carrier film 20. As a result, the top sides 301 of the electronic components 30 are substantially coplanar with the top side 101 of the leadframe 10. In this embodiment, the electronic components 30 are thinner than the leadframe 10 and may be resistors, capacitors, inductors or any other passive or active components.

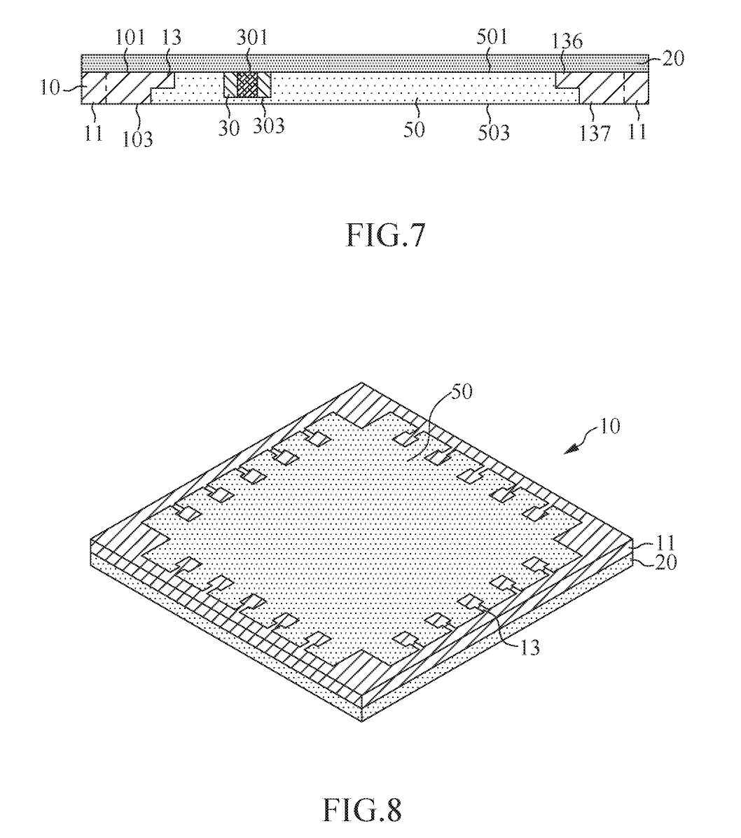

FIGS. 7 and 8 are cross-sectional schematic and bottom perspective views, respectively, of the structure provided with a compound layer 50. The compound layer 50 can be deposited by applying a molding material into the remaining spaces within the metal frame 11. The molding material can be applied by paste printing, compressive molding, transfer molding, liquid injection molding, spin coating, or other suitable methods. Then, a thermal process (or heat-hardened process) is applied to harden the molding material and to transform it into a solid molding compound. As a result, the compound layer 50 covers the bottom sides 303 of the electronic components 30 and the lower surfaces of the horizontally elongated portions 136 as well as sidewalls of the vertically projected portions 137 and sidewalls of the electronic components 30. By the stepped cross-section profile of the metal leads 13, the compound layer 50 can securely interlock with the metal leads 13 so as to prevent the metal leads 13 from being vertically forced apart from the compound layer 50 and also to avoid micro-cracking at the interface along the vertical direction. In this illustration, the top surface 501 of the compound layer 50 is substantially coplanar with the top side 101 of the leadframe 10 and the top sides 301 of the electronic components 30, whereas the bottom surface 503 of the compound layer 50 is substantially coplanar with the bottom side 103 of the leadframe 10 by planarization.

The compound layer 50 typically includes binder resins, fillers, hardeners, diluents, and additives. There is no particular limit to the binder resin that can be used in accordance with the present invention. For example, the binder resin may be at least one selected from the group consisting of an epoxy resin, a phenol resin, a polyimide resin, a polyurethane resin, a silicone resin, a polyester resin, an acrylate, bismaleimide (BMI), and equivalents thereof. The binder resin provides intimate adhesion between an adherent and the filler. The binder resin also serves to elicit thermal conductivity through chain-like connection of the filler. The binder resin may also improve physical and chemical stability of the molding compound.

Additionally, there is no particular limit to the filler that can be used in accordance with the present invention. For example, a thermally conductive filler may be selected from the group consisting of aluminum oxide, aluminum nitride, silicon carbide, tungsten carbide, boron carbide, silica and equivalents thereof. More specifically, the compound layer 50 may become thermally conductive or have low CTE if suitable fillers are dispersed therein. For example, aluminum nitride (AlN) or silicon carbide (SiC) has relatively high thermal conductivity, high electrical resistance, and a relatively low coefficient of thermal expansion (CTE). Accordingly, when the compound layer 50 employs these kinds of materials as fillers, the compound layer 50 would exhibit improved heat dissipation performance, electrical isolation performance and show inhibition of delamination or cracking of circuitry or interfaces due to low CTE. The maximum particle size of the thermally conductive filler may be 25 μm or less. The content of the filler may be in the range of 10 to 90% by weight. If the content of the thermally conductive filler is less than 10% by weight, insufficient thermal conductivity and excessively low viscosity may result. Low viscosity means that it may be difficult to handle and control the process due to excessively easy outflow of the resin from the tool during dispensing or molding process. On the other hand, if the content of the filler is higher than 90% by weight, decreased adhesive strength and excessively high viscosity of the molding material may result. High viscosity of the molding material results in poor workability due to no outflow of the material from the tool during the dispensing or molding process. Additionally, the compound layer 50 may include more than one type of fillers. For example, the second filler may be polytetrafluoroethylene (PTFE) so as to further improve electrical isolation property of the compound layer 50. In any case, the compound layer 50 preferably has an elastic modulus larger than 1.0 GPa and a linear coefficient of thermal expansion in a range from about 5×10⁻⁶ K⁻¹ to about 15×10⁻⁶ K⁻¹.

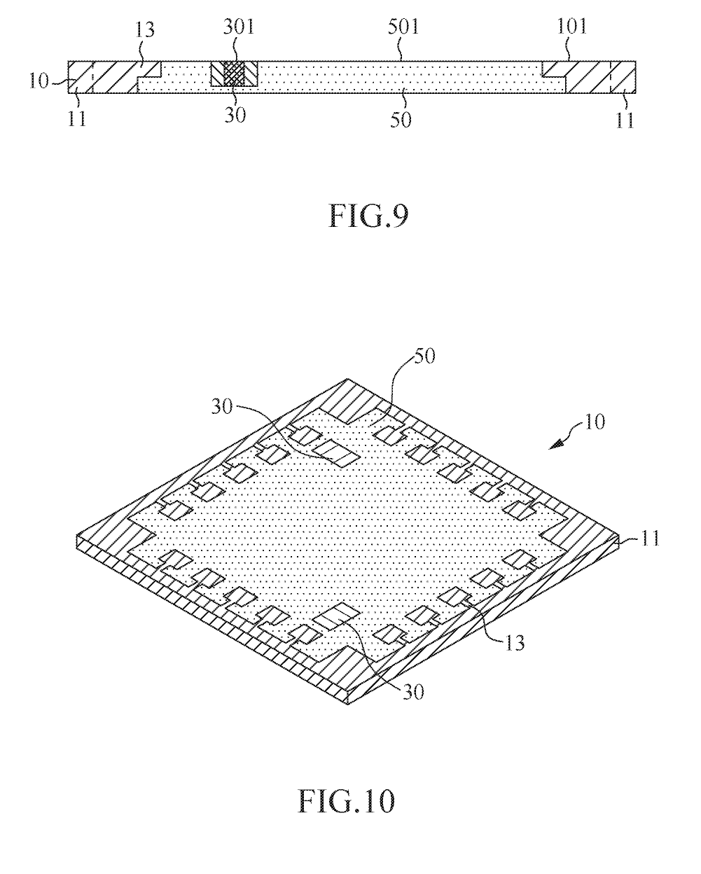

FIGS. 9 and 10 are cross-sectional schematic and top perspective views, respectively, of the structure after removal of the carrier film 20. The carrier film 20 is detached from the leadframe 10, the electronic components 30 and the compound layer 50. As a result, the top side 101 of the leadframe 10, the top sides 301 of the electronic components 30 and the top surface 501 of the compound layer 50 are exposed from above.

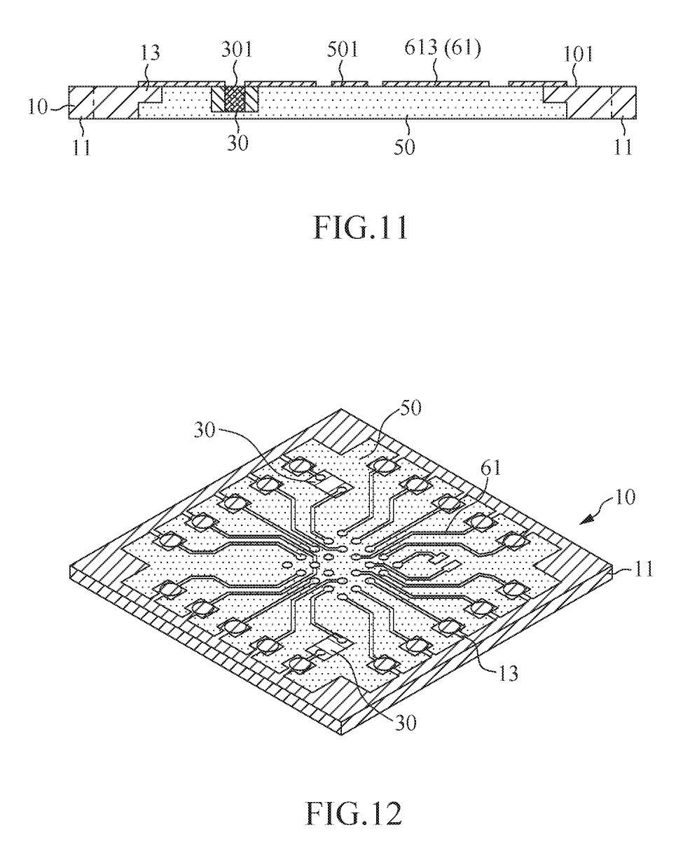

FIGS. 11 and 12 are cross-sectional schematic and top perspective views, respectively, of the structure provided with a top routing circuitry 61 by metal pattern deposition described below. The top surface of the structure can be metallized to form an electrically conductive layer (typically a copper layer) as a single layer or multiple layers by numerous techniques, such as electroplating, electroless plating, evaporating, sputtering or their combinations. The electrically conductive layer can be made of Cu, Ni, Ti, Au, Ag, Al, their combinations, or other suitable electrically conductive materials. Typically, a seeding layer is formed on the topmost surface of the structure prior to the electrically conductive layer is electroplated to a desirable thickness. The seeding layer may consist of a diffusion barrier layer and a plating bus layer. The diffusion barrier layer is to counterbalance oxidation or corrosion of the electrically conductive layer such as copper. In most cases, the diffusion barrier layer also acts as an adhesion promotion layer to the underlying material and is formed by physical vapor deposition (PVD) such as sputtered Ti or TiW with a thickness in a range from about 0.01 μm to about 0.1 μm. However, the diffusion barrier layer may be made of other materials, such as TaN, or other applicable materials and its thickness range is not limited to the range given above. The plating bus layer is typically made of the same material as the electrically conductive layer with a thickness in a range from about 0.1 μm to about 1 μm. For example, if the electrically conductive layer is copper, the plating bus layer would preferably be a thin film copper formed by physical vapor deposition or electroless plating. However, the plating bus layer may be made of other applicable materials such as silver, gold, chromium, nickel, tungsten, or combinations thereof and its thickness range is not limited to the range described above.

Following the deposition of the seeding layer, a photoresist layer (not shown) is formed over the seeding layer. The photoresist layer may be formed by a wet process, such as a spin-on process, or by a dry process, such as lamination of a dry film. After the photoresist layer is formed, the photoresist layer is patterned to form openings, which are then filled with plated metal such as copper to form the top routing circuitry 61. The plated metal layer typically has a thickness in a range from about 10 μm to about 100 μm. After metal plating, the exposed seeding layer is then removed by etching process to form electrically isolated conductive traces as desired. In this illustration, the top routing circuitry 61 is a top patterned metal layer 613 that has a uniform thickness and laterally extends on the top surface 501 of the compound layer 50 as well as the top side 101 of the leadframe 10 and the top sides 301 of the electronic components 30. As a result, the top routing circuitry 61 electrically couples the electronic components 30 to the metal leads 13.

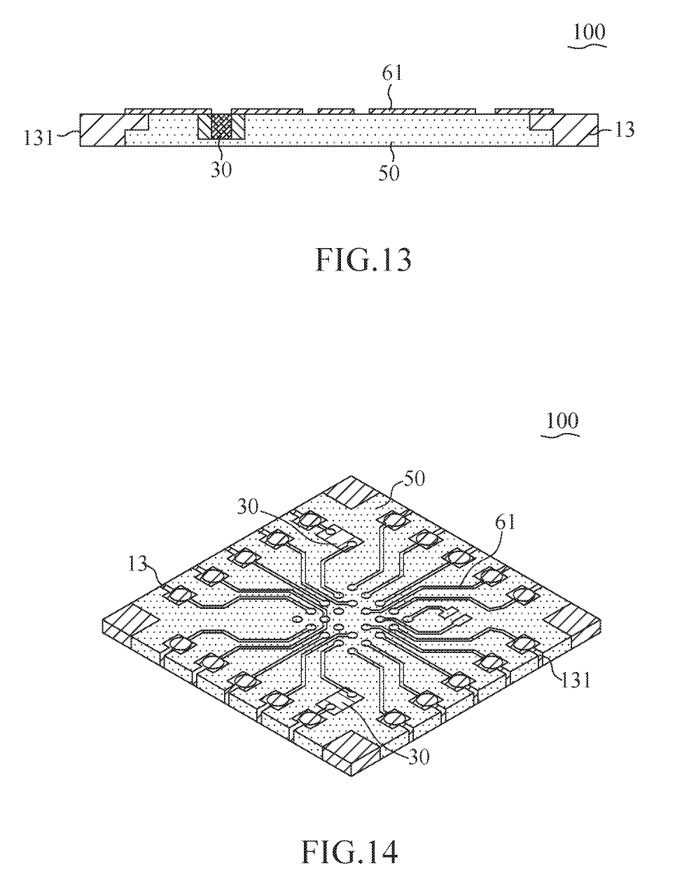

FIGS. 13 and 14 are cross-sectional schematic and top perspective views, respectively, of a leadframe substrate 100 separated from the metal frame 11. By a rotating saw or a trimming machine, the metal frame 11 is cut off to break the connection between the metal leads 13. Accordingly, the outer ends 131 of the metal leads 13 are situated at peripheral edges of the leadframe substrate 100 and have a lateral surface flush with peripheral edges of the compound layer 50.

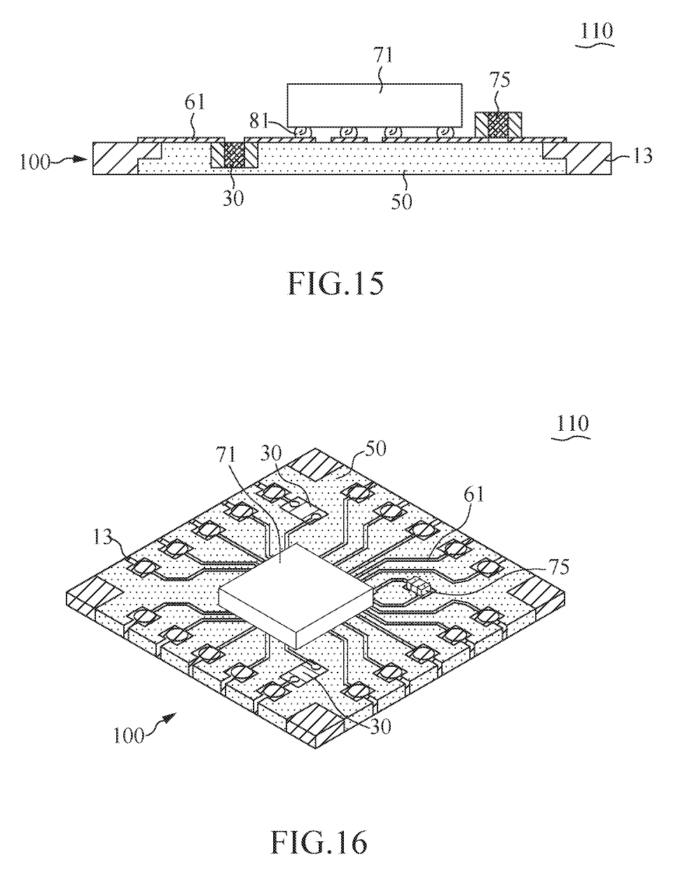

FIGS. 15 and 16 are cross-sectional schematic and top perspective views, respectively, of a semiconductor assembly 110 with a semiconductor device 71 and a passive component 75 electrically connected to the leadframe substrate 100 illustrated in FIGS. 13 and 14. The semiconductor device 71, illustrated as a chip, and the passive component 75 are mounted over the compound layer 50 and electrically coupled to the top routing circuitry 61. In this embodiment, the semiconductor device 71 is electrically coupled to the top routing circuitry 61 through conductive bumps 81.

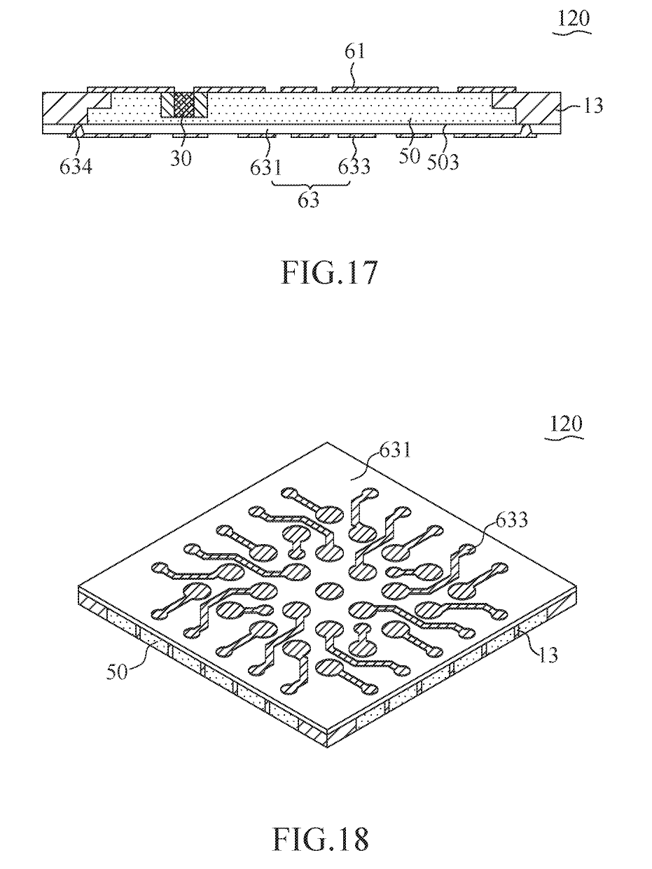

FIGS. 17 and 18 are cross-sectional schematic and bottom perspective views, respectively, of another aspect of the leadframe substrate according to the first embodiment of the present invention. The leadframe substrate 120 is similar to that illustrated in FIGS. 13 and 14, except that it further includes a bottom routing circuitry 63 disposed on the bottom surface 503 of the compound layer 50 and electrically coupled to the metal leads 13. In this illustration, the bottom routing circuitry 63 is a bottom multi-layered buildup circuitry and includes a bottom dielectric layer 631 and a bottom patterned metal layer 633 in an alternate fashion. The bottom dielectric layer 631 is deposited typically by lamination or coating, and contacts and covers and extends laterally on the compound layer 50 and the metal leads 13 from below. The bottom dielectric layer 631 typically has a thickness of 50 microns, and can be made of epoxy resin, glass-epoxy, polyimide, or the like. The bottom patterned metal layer 633 extends laterally on the bottom dielectric layer 631 and includes metallized vias 634 in the bottom dielectric layer 631. Accordingly, the bottom routing circuitry 63 can be electrically coupled to the metal leads 13 through the metallized vias 634 embedded in the bottom dielectric layer 631 and in contact with the metal leads 13.

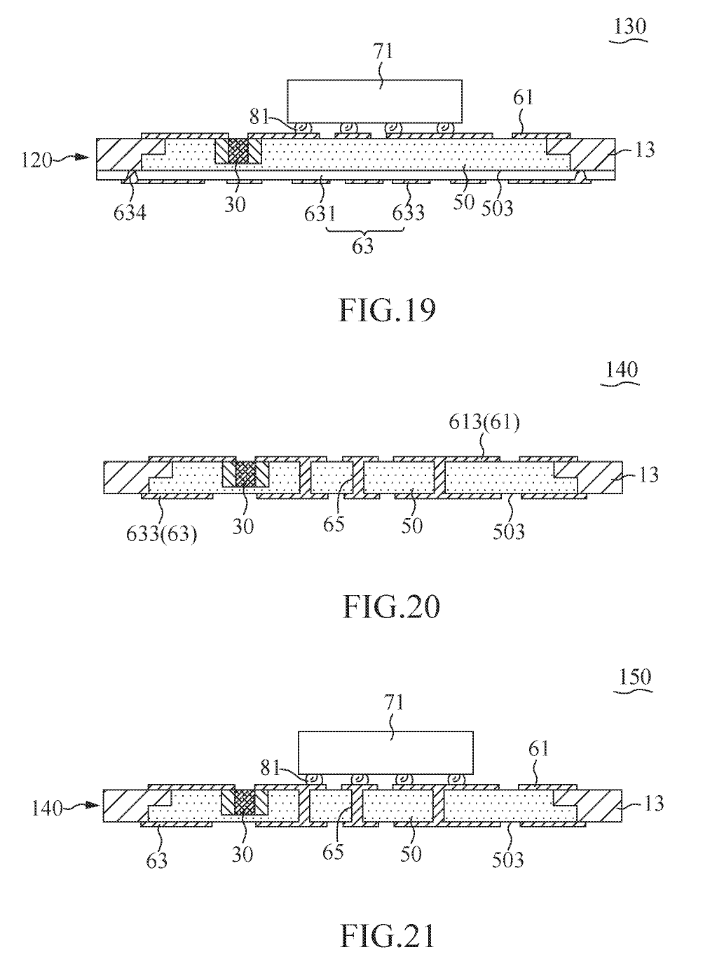

FIG. 19 is a cross-sectional schematic view of a semiconductor assembly 130 with a semiconductor device 71 electrically connected to the leadframe substrate 120 illustrated in FIG. 17. The semiconductor device 71 is mounted over the compound layer 50 and electrically coupled to the top routing circuitry 61 through conductive bumps 81.

FIG. 20 is a cross-sectional schematic view of yet another aspect of the leadframe substrate according to the first embodiment of the present invention. The leadframe substrate 140 is similar to that illustrated in FIGS. 13 and 14, except that it further includes a bottom routing circuitry 63 and metallized through holes 65. In this illustration, the bottom routing circuitry 63 is a bottom patterned metal layer 633 formed by metal deposition using photolithographic process and thinner than the metal leads 13. The bottom patterned metal layer 633 has a uniform thickness and laterally extends on the bottom surface 503 of the compound layer 50 as well as the bottom sides 103 of the metal leads 13. The metallized through holes 65 extend through the compound layer 50 and contact and provide electrical connection between the top routing circuitry 61 and the bottom routing circuitry 63.

FIG. 21 is a cross-sectional schematic view of a semiconductor assembly 150 with a semiconductor device 71 electrically connected to the leadframe substrate 140 illustrated in FIG. 20 through conductive bumps 81. The semiconductor device 71 is mounted over the top surface of the compound layer 50 and electrically connected to the electronic component 30 through the top routing circuitry 61 and to the bottom routing circuitry 63 through the top routing circuitry 61 and the metallized through holes 65 as well as the metal leads 13.

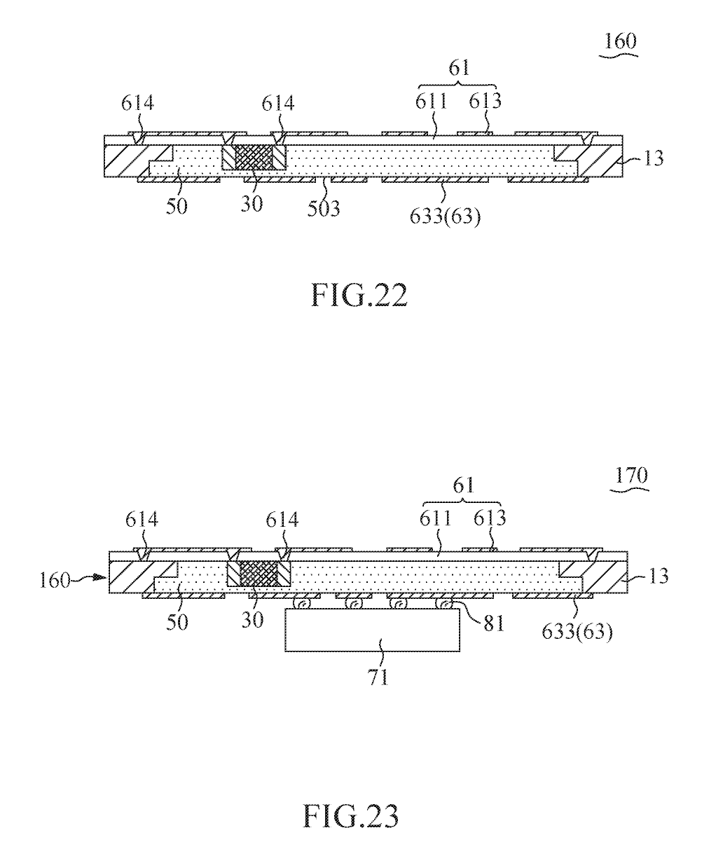

FIG. 22 is a cross-sectional schematic view of yet another aspect of the leadframe substrate according to the first embodiment of the present invention. The leadframe substrate 160 is similar to that illustrated in FIGS. 13 and 14, except that the top routing circuitry 61 is a top multi-layered buildup circuitry and a bottom routing circuitry 63 is further deposited on the bottom surface 503 of the compound layer 50. In this illustration, the top routing circuitry 61 includes a top dielectric layer 611 and a top patterned metal layer 613 in an alternate fashion, whereas the bottom routing circuitry 63 is a bottom patterned metal layer 633. The top dielectric layer 611 covers and extends laterally on the electronic component 30, the compound layer 50 and the metal leads 13 from above. The top patterned metal layer 613 extends laterally on the top dielectric layer 611 and includes metallized vias 614 embedded in the top dielectric layer 611 and in contact with the metal leads 13 and the electronic component 30. The bottom patterned metal layer 633 laterally extends on the compound layer 50 and the metal leads 13 from below. Accordingly, the top routing circuitry 61 can be electrically coupled to the metal leads 13 and the electronic component 30 through the metallized vias 614, and the bottom routing circuitry 63 is electrically connected to the top routing circuitry 61 through the metal leads 13.

FIG. 23 is a cross-sectional schematic view of a semiconductor assembly 170 with a semiconductor device 71 electrically connected to the leadframe substrate 160 illustrated in FIG. 22. The semiconductor device 71 is electrically coupled to the bottom routing circuitry 63 through conductive bumps 81 in contact with the bottom patterned metal layer 633.

### Embodiment 2

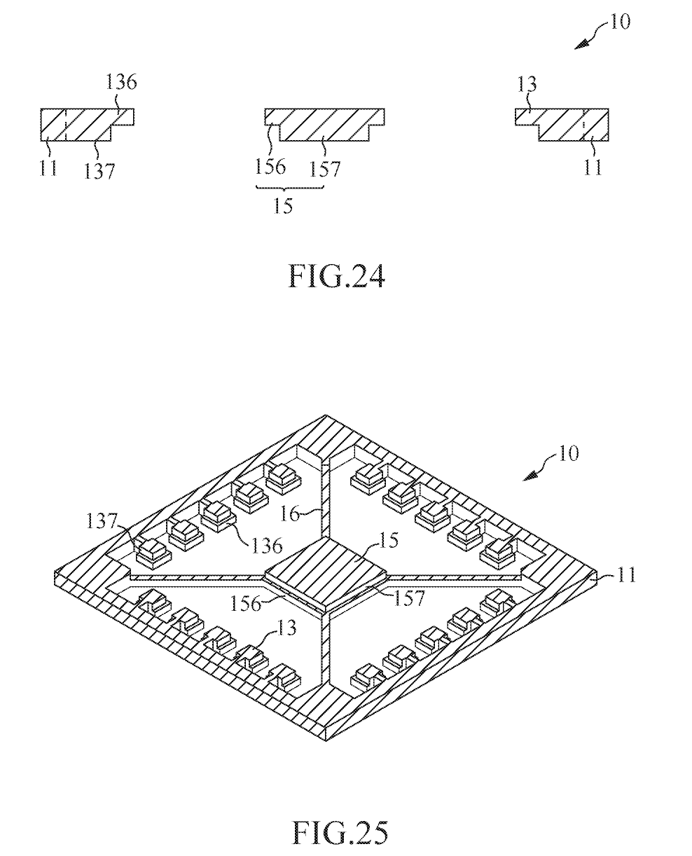

FIGS. 24-37 are schematic views showing a method of making a leadframe substrate having a thermal paddle in accordance with the second embodiment of the present invention.

For purposes of brevity, any description in Embodiment 1 is incorporated herein insofar as the same is applicable, and the same description need not be repeated.

FIGS. 24 and 25 are cross-sectional schematic and bottom perspective views, respectively, of a leadframe 10. In this embodiment, the leadframe 10 is similar to that illustrated in FIGS. 1-2, except that it further includes a thermal paddle 15 and a plurality of tie bars 16. The thermal paddle 15 is a metal paddle located at a predetermined area within the metal frame 11 and connected to the metal frame 11 by the tie bars 16. Additionally, the thermal paddle 15 and the tie bars 16 are also selectively half-etched from their bottom side. Accordingly, the tie bars 16 have reduced thickness, and the thermal paddle 15 have stepped peripheral edges. The thermal paddle 15 has a base portion 156 and a post portion 157. The post portion 157 has a smaller lateral dimension than the base portion 156 and protrudes from a lower surface of the base portion 156 in the downward direction. In this illustration, the horizontally elongated portions 136 and the base portion 156 have upper surfaces flush with each other, whereas the vertically projected portions 137 and the post portion 157 have exterior surfaces flush with each other.

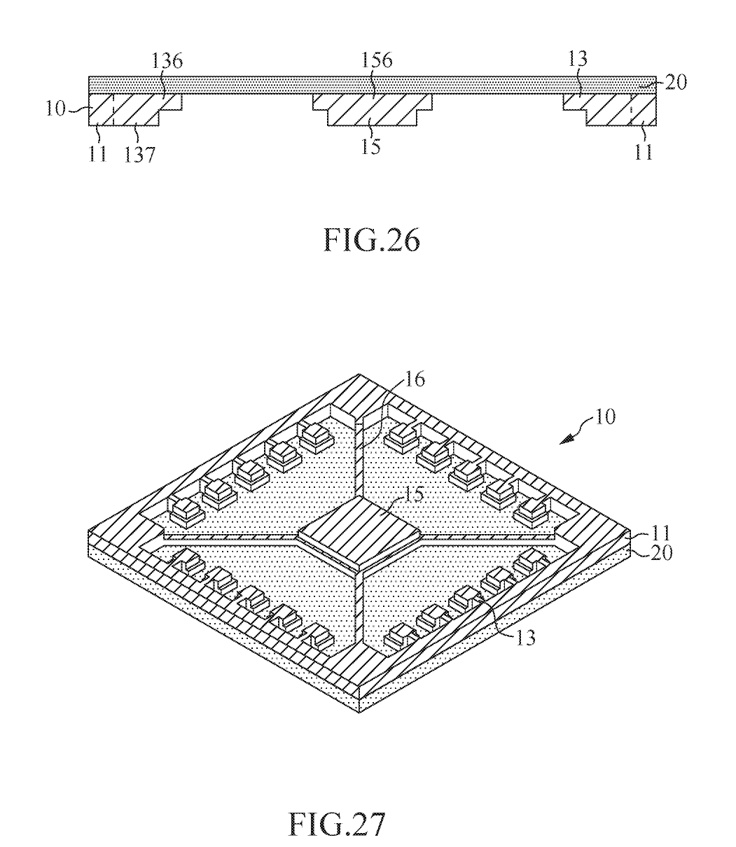

FIGS. 26 and 27 are cross-sectional schematic and bottom perspective views, respectively, of the structure with the leadframe 10 attached to a carrier film 20. The leadframe 10 is attached to the carrier film 20, with the horizontally elongated portions 136 of the metal leads 13 and the base portion 156 of the thermal paddle 15 as well as the metal frame 11 and the tie bars 16 in contact with the carrier film 20.

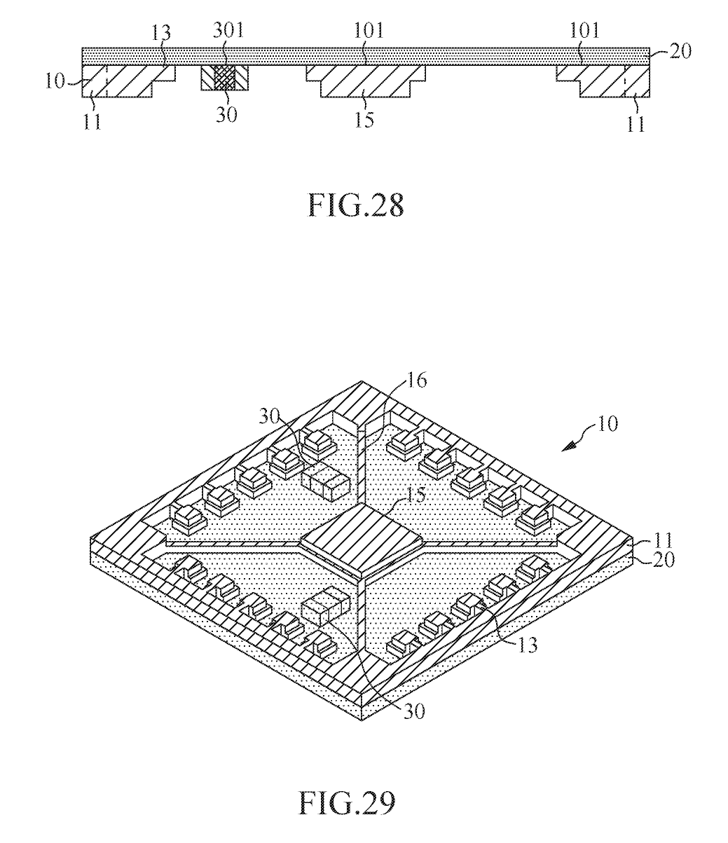

FIGS. 28 and 29 are cross-sectional schematic and bottom perspective views, respectively, of the structure with electronic components 30 attached to the carrier film 20. The top sides 301 of the electronic components 30 contact the carrier film 20 and are substantially coplanar with the top sides 101 of the metal leads 13 and the thermal paddle 15.

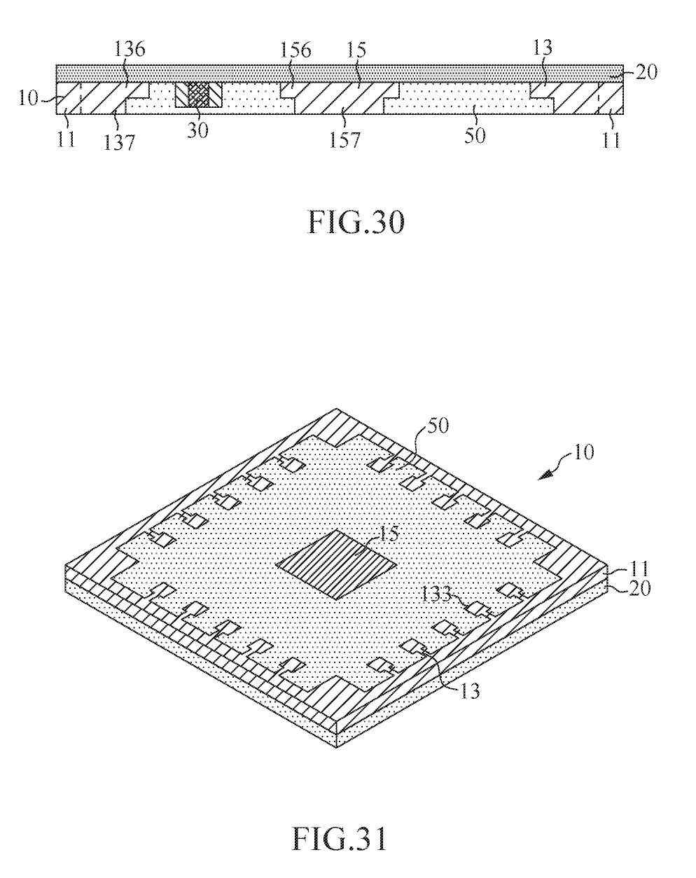

FIGS. 30 and 31 are cross-sectional schematic and bottom perspective views, respectively, of the structure provided with a compound layer 50. The compound layer 50 fills in spaces between the metal leads 13 and laterally extends beyond the inner ends 133 of the metal leads 13 to cover sidewalls of the thermal paddle 15 and encapsulate the electronic components 30. In this illustration, the compound layer 50 covers the lower surfaces of the horizontally elongated portions 136 and the base portion 156 as well as sidewalls of the vertically projected portions 137 and the post portion 157. As a result, the stepped peripheral edges of the metal leads 13 and the thermal paddle 15 can securely interlock with the compound layer 50 so as to prevent the metal leads 13 and the thermal paddle 15 from being vertically forced apart from the compound layer 50 and also to avoid micro-cracking at the interface along the vertical direction.

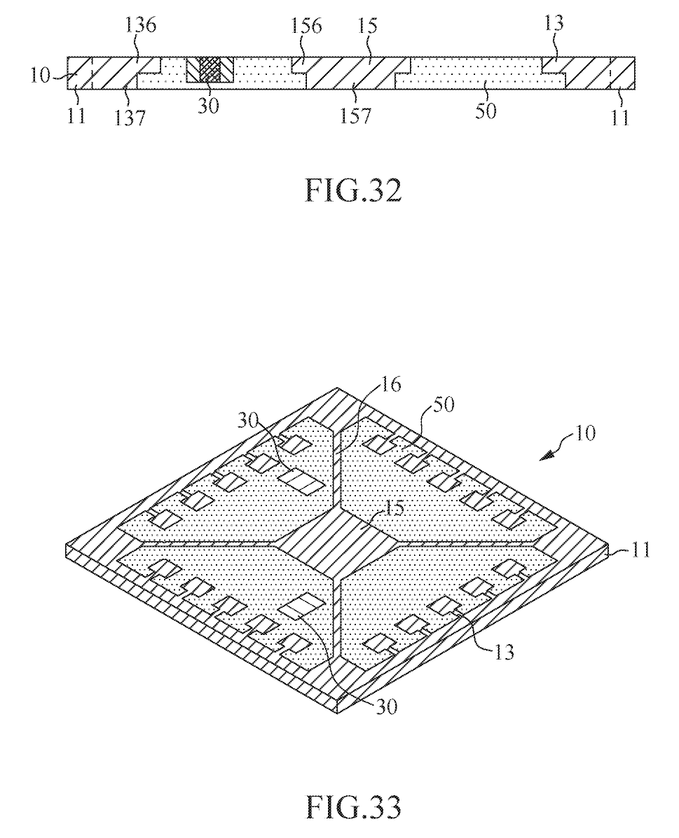

FIGS. 32 and 33 are cross-sectional schematic and top perspective views, respectively, of the structure after removal of the carrier film 20. The carrier film 20 is detached from the leadframe 10, the electronic components 30 and the compound layer 50. As a result, the horizontally elongated portions 136 of the metal leads 13 and the base portion 156 of the thermal paddle 15 as well as the electronic components 30 are exposed from above.

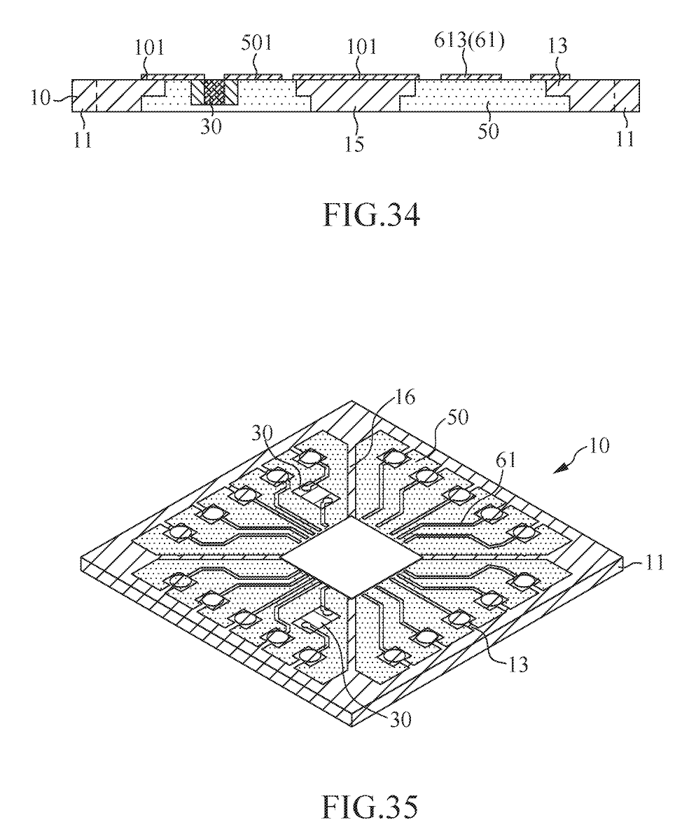

FIGS. 34 and 35 are cross-sectional schematic and top perspective views, respectively, of the structure provided with a top routing circuitry 61 by metal pattern deposition. The top routing circuitry 61 is a top patterned metal layer 613 that laterally extends on the top surface 501 of the compound layer 50 and the top sides 101 of the metal leads 13 and the thermal paddle 15. As a result, the top routing circuitry 61 electrically couples the electronic components 30 to the metal leads 13 and is thermally conductible to the thermal paddle 15.

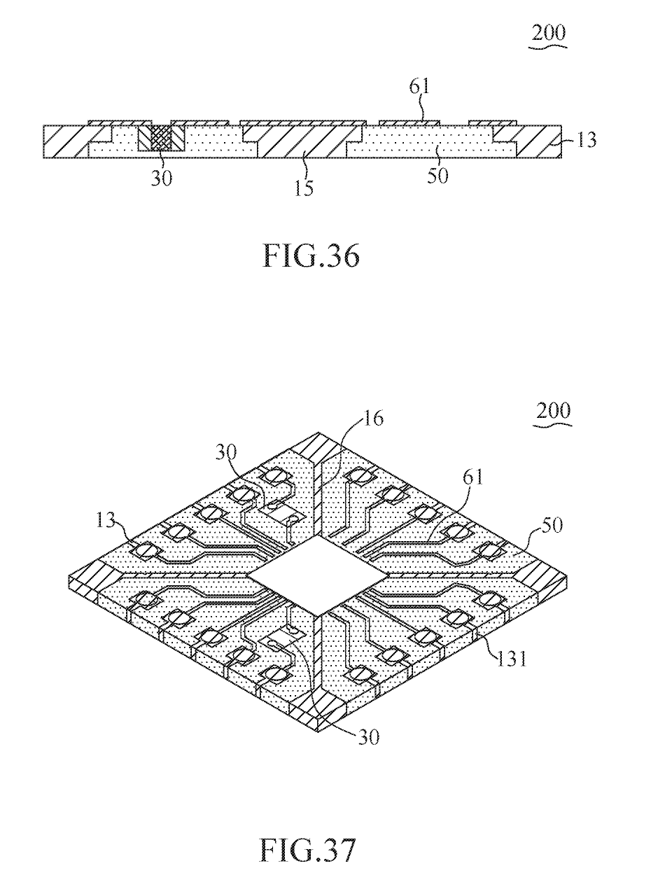

FIGS. 36 and 37 are cross-sectional schematic and top perspective views, respectively, of the structure after removal of the metal frame 11. By cutting off the metal frame 11, the connection between the outer ends 131 of the metal leads 13 is broken. As a result, a leadframe substrate 200 is accomplished and includes metal leads 13, a thermal paddle 15, tie bars 16, electronic components 30, a compound layer 50 and a top routing circuitry 61.

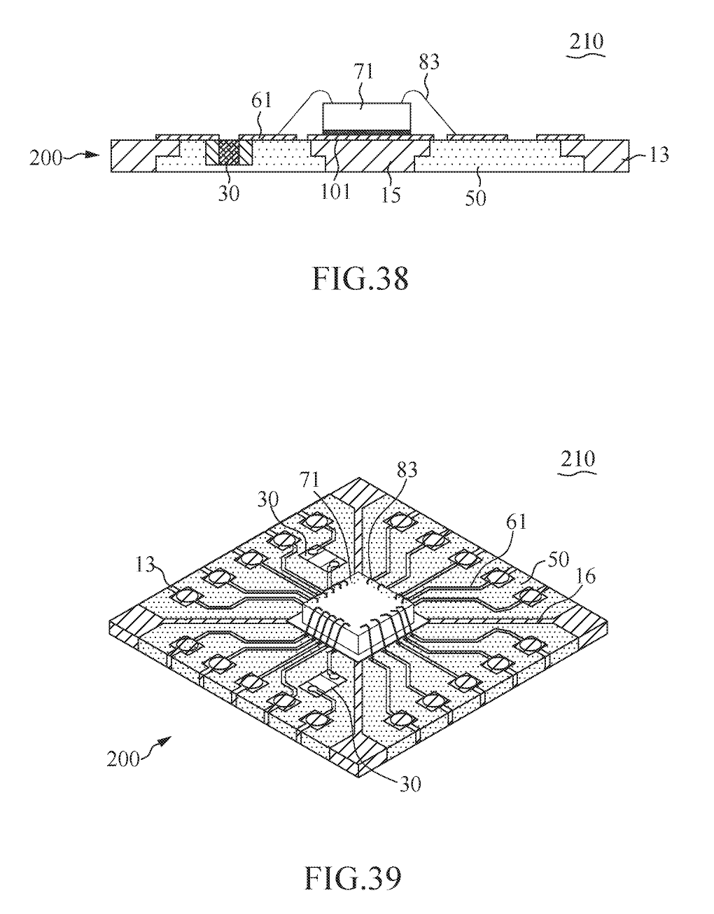

FIGS. 38 and 39 are cross-sectional schematic and top perspective views, respectively, of a semiconductor assembly 210 with a semiconductor device 71 electrically connected to the leadframe substrate 200 illustrated in FIGS. 36 and 37. The semiconductor device 71 is mounted over the top side 101 of the thermal paddle 15 and electrically coupled to the top routing circuitry 61 through bonding wires 83.

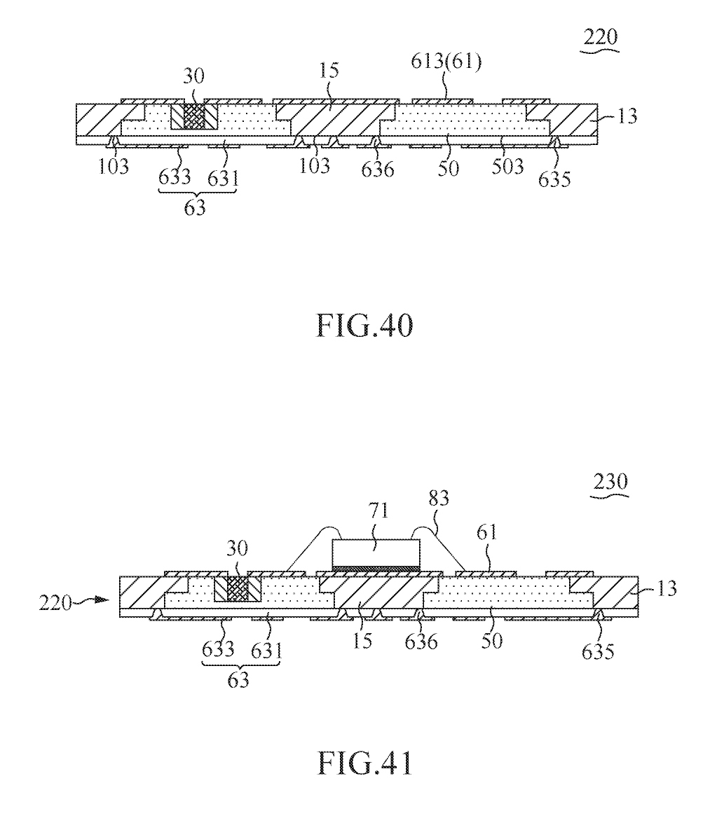

FIG. 40 is a cross-sectional schematic view of another aspect of the leadframe substrate according to the second embodiment of the present invention. The leadframe substrate 220 is similar to that illustrated in FIGS. 36 and 37, except that it further includes a bottom routing circuitry 63. In this aspect, the bottom routing circuitry 63 is a bottom multi-layered buildup circuitry and includes a bottom dielectric layer 631 and a bottom patterned metal layer 633 in an alternate fashion. The bottom dielectric layer 631 covers and extends laterally on the compound layer 50, the metal leads 13 and the thermal paddle 15 from below. The bottom patterned metal layer 633 extends laterally on the bottom dielectric layer 631 and includes first metallized vias 635 in contact with the metal leads 13 and second metallized vias 636 in contact with the thermal paddle 15. As a result, the bottom routing circuitry 63 is electrically coupled to the metal leads 13 through the first metallized vias 635 and thermally conductible to the thermal paddle 15 through the second metallized vias 636.

FIG. 41 is a cross-sectional schematic view of a semiconductor assembly 230 with a semiconductor device 71 electrically connected to the leadframe substrate 220 illustrated in FIG. 40. The semiconductor device 71 is face-up mounted over the thermal paddle 15 and electrically coupled to the top routing circuitry 61 through bonding wires 83.

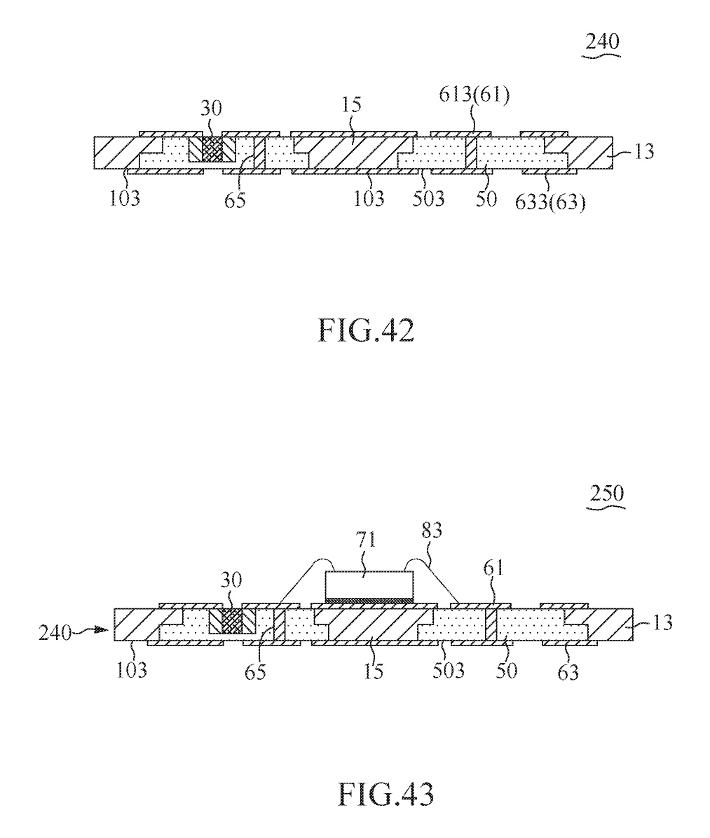

FIG. 42 is a cross-sectional schematic view of yet another aspect of the leadframe substrate according to the second embodiment of the present invention. The leadframe substrate 240 is similar to that illustrated in FIG. 36, except that it further includes a bottom routing circuitry 63 and metallized through holes 65. In this illustration, the bottom routing circuitry 63 is a bottom patterned metal layer 633 that laterally extends on the compound layer 50 as well as the metal leads 13 and the thermal paddle 15 from below. The metallized through holes 65 extends through the compound layer 50 and electrically connect the top patterned metal layer 613 to the bottom patterned metal layer 633.

FIG. 43 is a cross-sectional schematic view of a semiconductor assembly 250 with a semiconductor device 71 electrically connected to the leadframe substrate 240 illustrated in FIG. 42. The semiconductor device 71 is face-up mounted over the thermal paddle 15 and electrically coupled to the top routing circuitry 61 through bonding wires 83.

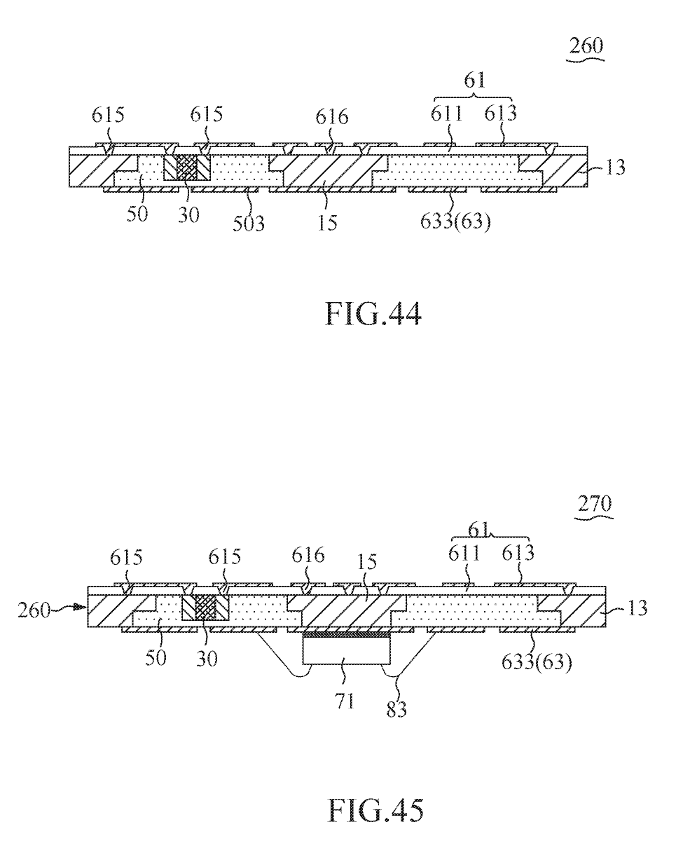

FIG. 44 is a cross-sectional schematic view of yet another aspect of the leadframe substrate according to the second embodiment of the present invention. The leadframe substrate 260 is similar to that illustrated in FIG. 36, except that the top routing circuitry 61 is a top multi-layered buildup circuitry and a bottom routing circuitry 63 is further deposited on the bottom surface 503 of the compound layer 50. In this illustration, the top routing circuitry 61 includes a top dielectric layer 611 and a top patterned metal layer 613 in an alternate fashion, whereas the bottom routing circuitry 63 is a bottom patterned metal layer 633. The top dielectric layer 611 covers and extends laterally on the electronic component 30, the compound layer 50, the metal leads 13 and the thermal paddle 15 from above. The top patterned metal layer 613 extends laterally on the top dielectric layer 611 and includes first metallized vias 615 in contact with the metal leads 13 and the electronic component 30 and second metallized vias 616 in contact with the thermal paddle 15. The bottom patterned metal layer 633 laterally extends on the compound layer 50, the metal leads 13 and the thermal paddle 15 from below. Accordingly, the top routing circuitry 61 can electrically connect the electronic component 30 to the metal leads 13 through the first metallized vias 615 and is thermally conductible to the thermal paddle 15 through the second metallized vias 616, whereas the bottom routing circuitry 63 is electrically connected to the top routing circuitry 61 through the metal leads 13.

FIG. 45 is a cross-sectional schematic view of a semiconductor assembly 270 with a semiconductor device 71 electrically connected to the leadframe substrate 260 illustrated in FIG. 44. The semiconductor device 71 is attached to the thermal paddle 15 from below and electrically coupled to the bottom routing circuitry 63 through bonding wires 83.

### Embodiment 3

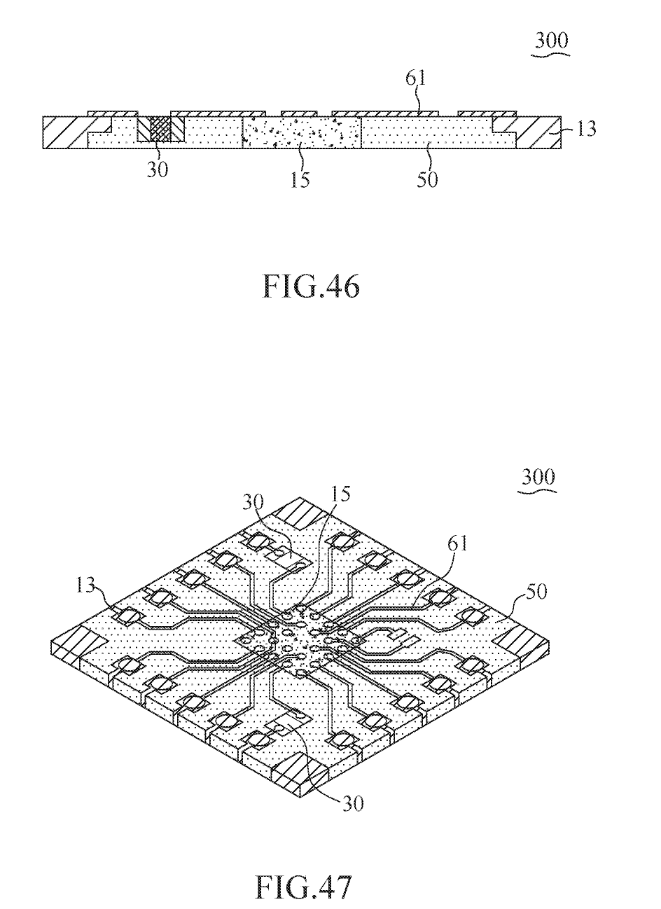

FIGS. 46 and 47 are cross-sectional schematic and top perspective views, respectively, of a leadframe substrate having a thermally conductive and electrically insulating paddle as the thermal paddle in accordance with the third embodiment of the present invention.

For purposes of brevity, any description in Embodiments above is incorporated herein insofar as the same is applicable, and the same description need not be repeated.

The leadframe substrate 300 is similar to that illustrated in FIG. 36, except that the thermal paddle 15 is a thermally conductive and electrically insulating paddle and the leadframe substrate 300 includes no tie bars integral with the thermal paddle 15. The thermally conductive and electrically insulating paddle typically is made of a material having high elastic modulus and low coefficient of thermal expansion (for example, 2×10⁻⁶ K⁻¹ to 10×10⁻⁶ K⁻¹), such as ceramic, silicon, glass or others. In this embodiment, the thermal paddle 15 is a ceramic paddle having a thickness substantially equal to the thickness of the metal leads 13, and the top routing circuitry 61 further laterally extends onto the thermal paddle 15 to provide electrical contacts on the top side of the thermal paddle 15. As a result, the thermal paddle 15 not only provides primary heat conduction, but also offers a CTE-compensated platform for a semiconductor device to be mounted thereon.

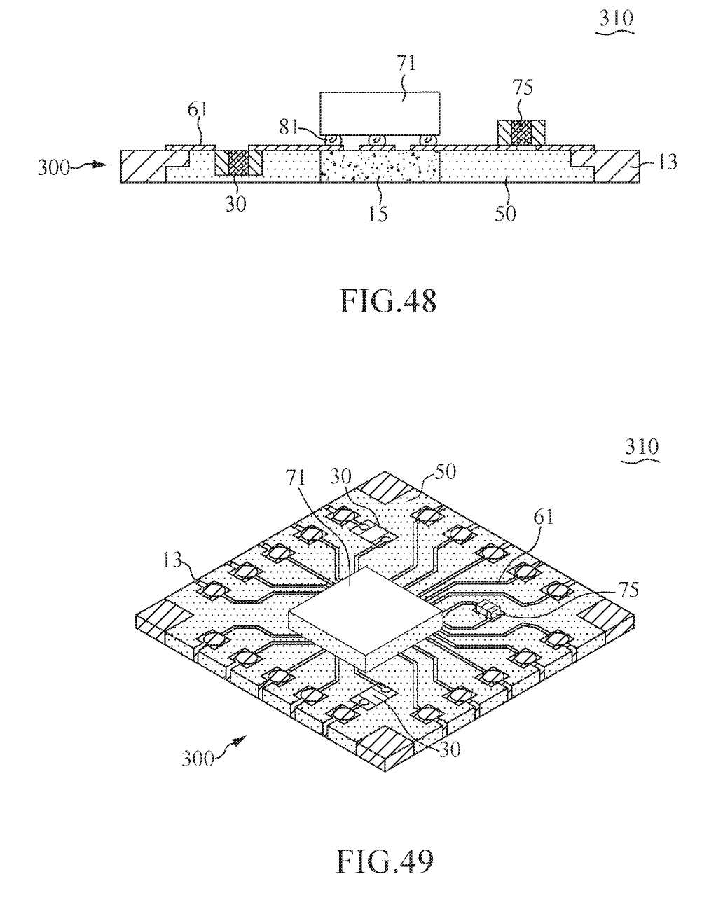

FIGS. 48 and 49 are cross-sectional schematic and top perspective views, respectively, of a semiconductor assembly 310 with a semiconductor device 71 and a passive component 75 electrically connected to the leadframe substrate 300 of FIGS. 46 and 47. The semiconductor device 71 is flip-chip mounted over the top side of the thermal paddle 15 and electrically coupled to the top routing circuitry 61 via conductive bumps 81. The passive component 75 is mounted over the top surface of the compound layer 50 and electrically coupled to the top routing circuitry 61.

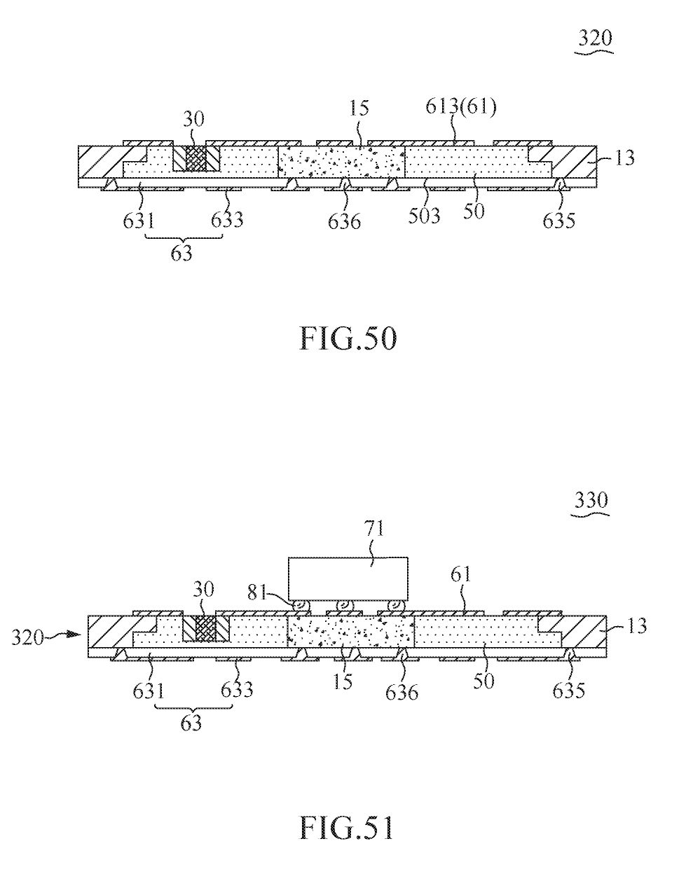

FIG. 50 is a cross-sectional schematic view of another aspect of the leadframe substrate according to the third embodiment of the present invention. The leadframe substrate 320 is similar to that illustrated in FIG. 46, except that it further includes a bottom routing circuitry 63. In this illustration, the bottom routing circuitry 63 is a bottom multi-layered buildup circuitry and includes a bottom dielectric layer 631 and a bottom patterned metal layer 633 in an alternate fashion. The bottom dielectric layer 631 contacts and covers and extends laterally on the compound layer 50, the metal leads 13 and the thermal paddle 15 from below. The bottom patterned metal layer 633 extends laterally on the bottom dielectric layer 631 and includes first metallized vias 635 in contact with the metal leads 13 and second metallized vias 636 in contact with the thermal paddle 15. Accordingly, the bottom routing circuitry 63 can be electrically coupled to the metal leads 13 through the first metallized vias 635 and thermally conductible to the thermal paddle 15 through the second metallized vias 636.

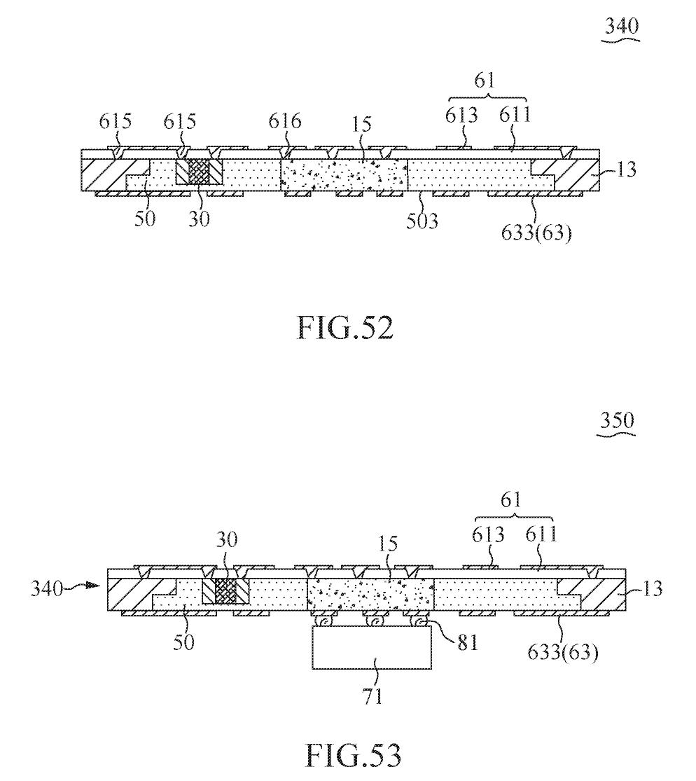

FIG. 51 is a cross-sectional schematic view of a semiconductor assembly 330 with a semiconductor device 71 electrically connected to the leadframe substrate 320 of FIG. 50. The semiconductor device 71 is flip-chip mounted over the top side of the thermal paddle 15 and electrically coupled to the top routing circuitry 61 via conductive bumps 81.

FIG. 52 is a cross-sectional schematic view of yet another aspect of the leadframe substrate according to the third embodiment of the present invention. The leadframe substrate 340 is similar to that illustrated in FIG. 46, except that the top routing circuitry 61 is a top multi-layered buildup circuitry and a bottom routing circuitry 63 is further deposited on the bottom surface 503 of the compound layer 50. In this illustration, the top routing circuitry 61 includes a top dielectric layer 611 and a top patterned metal layer 613 in an alternate fashion, whereas the bottom routing circuitry 63 is a bottom patterned metal layer 633. The top patterned metal layer 613 electrically connects the electronic component 30 to the metal leads 13 through first metallized vias 615 and is thermally conductible to the thermal paddle 15 through second metallized vias 616. The bottom patterned metal layer 633 is electrically connected to the top patterned metal layer 613 through the metal leads 13 and provides electrical contacts on the bottom side of the thermal paddle 15.

FIG. 53 is a cross-sectional schematic view of a semiconductor assembly 350 with a semiconductor device 71 electrically connected to the leadframe substrate 340 of FIG. 52. The semiconductor device 71 is flip-chip attached to the bottom side of the thermal paddle 15 and electrically coupled to the bottom routing circuitry 63 via conductive bumps 81.

As illustrated in the aforementioned embodiments, a distinctive leadframe substrate is configured to have a top routing circuitry electrically coupling an electronic component encapsulated in a compound layer to metal leads. The leadframe substrate of the present invention mainly includes a plurality of metal leads, an electronic component, a compound layer and a top routing circuitry. In a preferred embodiment, the metal leads are trimmed from a leadframe and can serve as horizontal and vertical signal transduction pathways or provide ground/power plane for power delivery and return; the electronic component is disposed at a predetermined area, with the top side of the electronic component being substantially coplanar with the top sides of the metal leads; the compound layer covers the sidewalls of the metal leads and encapsulates the electronic component and provides a platform for the top routing circuitry deposited thereon; and the top routing circuitry laterally extends on the top surface of the compound layer and is electrically coupled to the electronic component and the metal leads to increase routing flexibility of the leadframe substrate and electrically connect the electronic component to the metal leads.

Each of the metal leads preferably is an integral one-piece lead separated from a metal frame of the leadframe and has top and bottom sides and a lateral surface not covered by the compound layer. In a preferred embodiment, the metal leads have a thickness in a range from about 0.15 mm to about 1.0 mm and laterally extend at least to a perimeter coincident with peripheral edges of the compound layer. For secure bonds between the metal leads and the compound layer, the metal leads may have stepped peripheral edges interlocked with the compound layer. As a result, the compound layer also has a stepped cross-sectional profile where it contacts the metal leads so as to prevent the metal leads from being vertically forced apart from the compound layer and also to avoid micro-cracking at the interface along the vertical directions.

The electronic component may be a resistor, capacitor, inductor or any other passive or active component and is incorporated with the metal leads by the compound layer. In a preferred embodiment, the electronic component is thinner than the metal leads and has a bottom side covered by the compound layer.

The compound layer can be bonded to the metal leads and the electronic component by paste printing, compressive molding, transfer molding, liquid injection molding, spin coating, or other suitable methods. Preferably, the compound layer has a top surface substantially coplanar with the top sides of the metal leads and the electronic component, and a bottom surface substantially coplanar with the bottom sides of the metal leads. Further, the compound layer may have an elastic modulus larger than 1.0 GPa, a linear coefficient of thermal expansion in a range from about 5×10⁻⁶ K⁻¹ to about 15×10⁻⁶ K⁻¹. Additionally, for sufficient thermal conductivity and suitable viscosity, the compound layer may include thermally conductive fillers in a range of 10 to 90% by weight. For instance, the thermally conductive fillers may be made of aluminum nitride (AlN), aluminum oxide, silicon carbide (SiC), tungsten carbide, boron carbide, silica or the like and preferably has relatively high thermal conductivity, high electrical resistance, and a relatively low CTE. Accordingly, the compound layer would exhibit improved heat dissipation performance, electrical isolation performance and shows inhibition of delamination or cracking of the top routing circuitry deposited thereon or interfaces due to low CTE. Additionally, the maximum particle size of the thermally conductive fillers may be 25 μm or less.

In a thermally enhanced case, a thermal paddle may be further provided to serve as a primary heat conduction platform for the semiconductor device attached thereon, so that the heat generated by the semiconductor device can be conducted away. In a preferred embodiment, the thermal paddle is disposed about the inner ends of the metal leads, and has top and bottom sides substantially coplanar with the top and bottom sides of the metal leads as well as the top and bottom surfaces of the compound layer, respectively. The thermal paddle may be a metal paddle or a thermally conductive and electrically insulating paddle. The metal paddle can be made of the same material as the metal leads and connected to the metal frame by, for example, tie bars, before the trimming process. The thermally conductive and electrically insulating paddle can be made of ceramic, silicon, glass or others and typically has high elastic modulus and low coefficient of thermal expansion (for example, 2×10⁻⁶ K⁻¹ to 10×10⁻⁶ K⁻¹). As a result, the thermally conductive and electrically insulating paddle, having CTE matching a semiconductor device to be assembled thereon, provides a CTE-compensated platform for the semiconductor device, and thus internal stresses caused by CTE mismatch can be largely compensated or reduced. Likewise, the thermal paddle may have stepped peripheral edges interlocked with the compound layer. As a result, the compound layer also has a stepped cross-sectional profile where it contacts the thermal paddle so as to prevent the thermal paddle from being vertically forced apart from the compound layer and also to avoid micro-cracking at the interface along the vertical directions.

The top routing circuitry may be a top patterned metal layer formed by metal deposition using photolithographic process and having a uniform thickness less than the thickness of the metal leads. In a preferred embodiment, the top patterned metal layer contacts and laterally extends on the top surface of the compound layer and further laterally extends onto the top sides of the metal leads and the top side of the electronic component by a sputtering process and then an electrolytic plating process. In the thermally enhanced case, the top patterned metal layer may further extend onto the top side of the thermal paddle. For instance, the top patterned metal layer may extend onto the top side of the thermally conductive and electrically insulating paddle to provide electrical contacts on the thermally conductive and electrically insulating paddle so as to allow a semiconductor device to be flip-chip attached on the thermally conductive and electrically insulating paddle. Alternatively, the top patterned metal layer may extend onto the top side of the metal paddle for a semiconductor device to be face-up mounted thereon. As a result, the top routing circuitry can electrically connect the electronic component to the metal leads and provide electrical contacts on the compound layer or on the thermally conductive and electrically insulating paddle for device connection. For instance, a semiconductor device may be wire bonded to the top routing circuitry or flip-chip attached on the top routing circuitry. Alternatively, the top routing circuitry may be a top multi-layered buildup circuitry and include at least one top dielectric layer and at least one top patterned metal layer that extends through the top dielectric layer and extends laterally on the top dielectric layer. The top dielectric layer and the top patterned metal layer are serially formed in an alternate fashion and can be in repetition when needed. Accordingly, the top routing circuitry can electrically couple the electronic component to the metal leads and thermally conductible to the optional thermal paddle through metallized vias in the top dielectric layer.

Optionally, a bottom routing circuitry may be further deposited on the bottom surface of the compound layer and electrically connected to the top routing circuitry through the metal leads or metallized through holes in the compound layer. By double routing circuitries on two sides of the compound layer, the routing flexibility of the leadframe substrate can be enhanced. In a preferred embodiment, the bottom routing circuitry is a bottom multi-layered buildup circuitry that includes at least one bottom dielectric layer and at least one bottom patterned metal layer extending through the bottom dielectric layer and extending laterally on the bottom dielectric layer. The bottom dielectric layer and the bottom patterned metal layer are serially formed in an alternate fashion and can be in repetition when needed. Accordingly, the bottom routing circuitry can be electrically coupled to the metal leads and thermally conductible to the optional thermal paddle through metallized vias in the bottom dielectric layer. Alternatively, the bottom routing circuitry may be a bottom patterned metal layer having a uniform thickness less than the thickness of the metal leads. The bottom patterned metal layer can be deposited by metal deposition using photolithographic process and contact and laterally extend on the bottom surface of the compound layer and may further laterally extend onto the bottom sides of the metal leads. In the thermally enhanced case, the bottom patterned metal layer may further extend onto the bottom side of the thermal paddle. For instance, the bottom patterned metal layer may extend onto the bottom side of the thermally conductive and electrically insulating paddle to provide electrical contacts on the thermally conductive and electrically insulating paddle so as to allow a semiconductor device to be flip-chip attached on the thermally conductive and electrically insulating paddle. Alternatively, the bottom patterned metal layer may extend onto the bottom side of the metal paddle for a semiconductor device to be mounted thereon. As a result, the bottom routing circuitry is electrically connected to the top routing circuitry and may provide electrical contacts on the compound layer or on the thermally conductive and electrically insulating paddle for device connection. For instance, a semiconductor device may be wire bonded to the bottom routing circuitry or flip-chip attached on the bottom routing circuitry.

The present invention also provides a semiconductor assembly in which a semiconductor device such as chip is electrically connected to the aforementioned leadframe substrate. For instance, the semiconductor device may be electrically coupled to the top patterned metal layer and further electrically connected to the bottom multi-layered buildup circuitry through the metal leads. Alternatively, the semiconductor device may be electrically coupled to the bottom patterned metal layer and further electrically connected to the top multi-layered buildup circuitry through the metal leads. Specifically, the semiconductor device can be electrically connected to the top routing circuitry or the bottom routing circuitry using a wide variety of connection media including conductive bumps (such as gold or solder bumps) on the top routing circuitry or the bottom routing circuitry, or bonding wires attached to the top routing circuitry or the bottom routing circuitry. In the thermally enhanced case, the semiconductor device can be attached to the top side or the bottom side of the thermal paddle, and the heat generated by the semiconductor device can be conducted away through the thermal paddle.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The semiconductor device can be a packaged or unpackaged chip. Furthermore, the semiconductor device can be a bare chip, or a wafer level packaged die, etc.

The term “cover” refers to incomplete or complete coverage in a vertical and/or lateral direction. For instance, the compound layer covers sidewalls of the metal leads regardless of whether another element is between the metal leads and the compound layer.

The phrase “attached to” includes contact and non-contact with a single or multiple support element(s). For instance, in a preferred embodiment, the semiconductor device can be attached to the metal paddle regardless of whether the semiconductor device is separated from the metal paddle by the top routing circuitry or the bottom routing circuitry.

The phrases “electrical connection”, “electrically connected” and “electrically coupled” refer to direct and indirect electrical connection. For instance, in a preferred embodiment, the semiconductor device can be electrically connected to the metal leads by the top routing circuitry or the bottom routing circuitry but does not contact the metal leads.

The leadframe substrate according to the present invention has numerous advantages. The thermal paddle establishes a heat dissipation pathway for spreading out the heat generated by the semiconductor device. The compound layer provides robust mechanical bonds between the metal leads and the thermal paddle and between the metal leads and the electronic component, and offers a dielectric platform for the top routing circuitry and the bottom routing circuitry deposited thereon. The metal leads provide primary horizontal and vertical routing, and the top routing circuitry and the bottom routing circuitry offer further routing to increase routing flexibility of the leadframe substrate and electrically connects the electronic component to the metal leads. The leadframe substrate made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A leadframe substrate, comprising:
a plurality of metal leads each having an inner end directed toward a predetermined area and an outer end situated farther away from the predetermined area than the inner end;
an electronic component that is disposed at the predetermined area and has a top side substantially coplanar with top sides of the metal leads;
a compound layer that fills in spaces between the metal leads and laterally extends beyond the inner ends of the metal leads and into the predetermined area and encapsulates the electronic component, wherein the compound layer has a top surface substantially coplanar with the top sides of the metal leads; and
a top routing circuitry disposed on the top surface of the compound layer and electrically coupling the electronic component to at least one of the metal leads.

2. The leadframe substrate of claim 1, wherein the electronic component is thinner than the metal leads.

3. The leadframe substrate of claim 1, wherein the top routing circuitry is a top multi-layered buildup circuitry.

4. The leadframe substrate of claim 1, wherein each of the metal leads has stepped peripheral edges interlocked with the compound layer.

5. The leadframe substrate of claim 1, further comprising a thermal paddle disposed at the predetermined area and having sidewalls bonded to the compound layer.

6. The leadframe substrate of claim 1, further comprising a bottom routing circuitry disposed at a bottom surface of the compound layer and electrically connected to the top routing circuitry through the metal leads or metallized through holes in the compound layer.

7. The leadframe substrate of claim 5, wherein the thermal paddle is a thermally conductive and electrically insulating paddle or a metal paddle.

8. The leadframe substrate of claim 5, wherein the thermal paddle has a top side substantially coplanar with the top surface of the compound layer.

9. The leadframe substrate of claim 8, wherein the top routing circuitry further laterally extends onto the top side of the thermal paddle.

10. The leadframe substrate of claim 5, wherein the thermal paddle has stepped peripheral edges interlocked with the compound layer.

11. A semiconductor assembly, comprising:
the leadframe substrate of claim 1; and
a semiconductor device that is electrically coupled to the top routing circuitry.

12. The semiconductor assembly of claim 11, wherein the semiconductor device is electrically coupled to the top routing circuitry through conductive bumps or bonding wires.

13. The semiconductor assembly of claim 11, wherein the leadframe substrate further comprises a thermal paddle disposed at the predetermined area and having sidewalls bonded to the compound layer, and the semiconductor device is mounted over a top side of the thermal paddle.

14. The semiconductor assembly of claim 13, wherein the top routing circuitry further laterally extends onto the top side of the thermal paddle.

15. The semiconductor assembly of claim 11, wherein the leadframe substrate further comprises a bottom routing circuitry disposed at a bottom surface of the compound layer and electrically connected to the top routing circuitry through the metal leads or metallized through holes in the compound layer.

16. A semiconductor assembly, comprising:
the leadframe substrate of claim 6; and
a semiconductor device that is electrically coupled to the bottom routing circuitry.

17. The semiconductor assembly of claim 16, wherein the semiconductor device is electrically coupled to the bottom routing circuitry through conductive bumps or bonding wires.

18. The semiconductor assembly of claim 16, wherein the leadframe substrate further comprises a thermal paddle disposed at the predetermined area and having sidewalls bonded to the compound layer, and the semiconductor device is attached to a bottom side of the thermal paddle.

19. The semiconductor assembly of claim 18, wherein the bottom routing circuitry further laterally extends onto the bottom side of the thermal paddle.
